(19) United States
(12) Patent Application Publication
(10) Pub. No.: US 2024/0250062 A1
(43) Pub. Date: Jul. 25, 2024

(54) SEMICONDUCTOR DEVICE AND METHOD FOR MAKING THE SAME

(71) Applicant: STATS ChipPAC Pte. Ltd., Singapore (SG)

(72) Inventors: JinHee JUNG, Incheon (KR); ChangOh KIM, Incheon (KR); HeeSoo LEE, Incheon (KR)

(21) Appl. No.: 18/414,500

(22) Filed: Jan. 17, 2024

(30) Foreign Application Priority Data
Jan. 19, 2023 (CN) 202310095004.1

(51) Int. Cl. H01L 23/00; H01L 21/56; H01L 23/29; H01L 23/31; H01L 25/00; H01L 25/065

(52) U.S. Cl. CPC H01L 24/82; H01L 21/561; H01L 24/24; H01L 25/0655; H01L 25/50; H01L 21/568; H01L 23/295; H01L 23/3185; H01L 2224/24137; H01L 2224/245; H01L 2224/82005; H01L 2224/82103; H01L 2924/01013; H01L 2924/01028; H01L 2924/01029; H01L 2924/01047; H01L 2924/0105; H01L 2924/01079

(57) ABSTRACT

A method for making a semiconductor device is provided. The method includes: providing a semiconductor assembly comprising a first semiconductor die and a second semiconductor die, wherein a first interconnection structure is electrically coupled to the first semiconductor die and a second interconnection structure is electrically coupled to the second semiconductor die; depositing an encapsulant layer over the semiconductor assembly to encapsulate the first interconnection structure and the second interconnection structure, wherein the encapsulant layer comprises an additive activatable by laser; forming an interconnection channel in the encapsulant layer and activating the additive of the encapsulant layer in the interconnection channel as a seed layer by laser patterning, wherein the interconnection channel exposes and interconnects the first and the second interconnection structures; forming a conductive layer in the interconnection channel of the encapsulant layer; and forming an outer layer on the encapsulant layer to cover the conductive layer.

### TECHNICAL FIELD

The present application relates generally to semiconductor technology, and more particularly, to a semiconductor device and a method for making such semiconductor device.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, integrated passive devices (IPD), RF filters, sensors, heat sinks, or antennas. Particularly, in 5G devices, multi-tier SiP will be essential technology for many new 5G applications such as 5G, WRAN (Wireless Regional Area Network), radar sensor, and imaging, etc. Yet, conventional methods for forming redistribution layers in a SiP may be sophisticated with high cost, and the semiconductor device formed with such conventional methods may have limited performance and density.

Therefore, a need exists for a method for making a semiconductor device with reduced cost.

### SUMMARY OF THE INVENTION

An objective of the present application is to provide a method for making a semiconductor device with reduced cost.

According to an aspect of the present application, a method for making a semiconductor device is provided. The method may include: providing a semiconductor assembly comprising a first semiconductor die and a second semiconductor die, wherein a first interconnection structure is electrically coupled to the first semiconductor die and a second interconnection structure is electrically coupled to the second semiconductor die; depositing an encapsulant layer over the semiconductor assembly to encapsulate the first interconnection structure and the second interconnection structure, wherein the encapsulant layer comprises an additive activatable by laser; forming an interconnection channel in the encapsulant layer and activating the additive of the encapsulant layer in the interconnection channel as a seed layer by laser patterning, wherein the interconnection channel exposes and interconnects the first and the second interconnection structures; forming a conductive layer in the interconnection channel of the encapsulant layer; and forming an outer layer on the encapsulant layer to cover the conductive layer.

According to another aspect of the present application, a semiconductor device is provided. The semiconductor device may include: a semiconductor assembly comprising a first semiconductor die and a second semiconductor die, wherein a first interconnection structure and a second interconnection structure are electrically coupled to the first semiconductor die and the second semiconductor die, respectively; an encapsulant layer over the semiconductor assembly, wherein the encapsulant layer encapsulates the first interconnection structure and the second interconnection structure, wherein the encapsulant layer comprises an additive activatable by laser; a conductive layer formed in the encapsulant layer, wherein the conductive layer interconnects the first and the second interconnection structures of the semiconductor assembly; wherein the conductive layer is formed by activating the additive of the encapsulant layer as a seed layer using laser patterning and subsequent plating on the seed layer; and an outer layer formed on the encapsulant layer to cover the conductive layer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 shows a flowchart of a method for making a semiconductor device according to an embodiment of the present application.

FIGS. 2A to 21 are cross-sectional views illustrating various steps of a method for making a semiconductor device according to an embodiment of the present application.

FIGS. 3A to 31 are cross-sectional views illustrating various steps of a method for making a semiconductor device according to another embodiment of the present application.

FIG. 4 and FIG. 5 show cross-sectional views illustrating semiconductor devices according to other embodiments of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

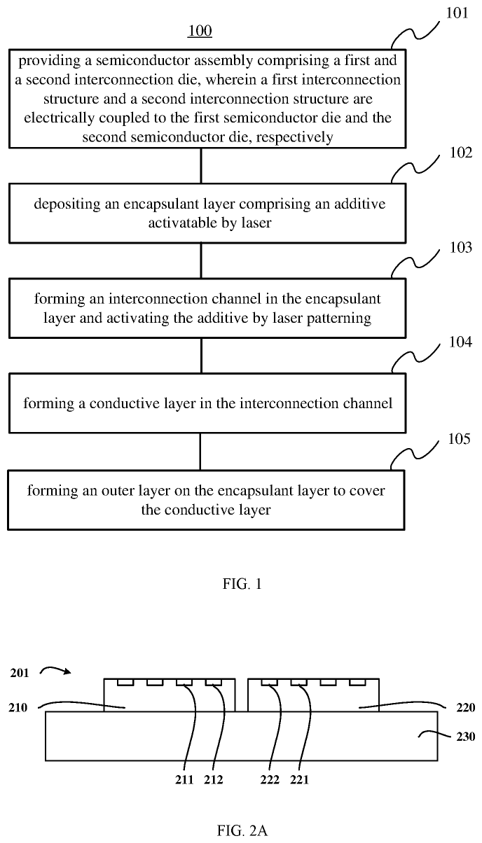

FIG. 1 shows a flowchart of a method for making a semiconductor device according to an embodiment of the present application. As shown in FIG. 1, in step 101, a semiconductor assembly including a first semiconductor die and a second semiconductor die is provided. In addition, the semiconductor assembly further has a first interconnection structure and a second interconnection structure, which are electrically coupled to the first semiconductor die and the second semiconductor die, respectively. In step 102, an encapsulant layer is deposited over the semiconductor assembly, such that the encapsulant layer encapsulates the semiconductor assembly including the first and second interconnection structures. The encapsulant layer includes an additive which is activatable by laser. In step 103, an interconnection channel is formed in the encapsulant layer, and the additive of the encapsulant layer in the interconnection channel is activated as a seed layer by laser patterning. The interconnection channel exposes and interconnects the first and the second interconnection structures. In step 104, a conductive layer is formed in the interconnection channel in the encapsulant layer. In step 105, an outer layer is formed on the encapsulant layer to cover the conductive layer. In this way, the first die and the second die of the semiconductor assembly can be electrically coupled with each other through the conductive layer within the interconnection channel which connects the first interconnection structure and the second interconnection structure with each other, thereby forming a compact system-in-package with two or more semiconductor dice. Steps of the method are illustrated with more details as below.

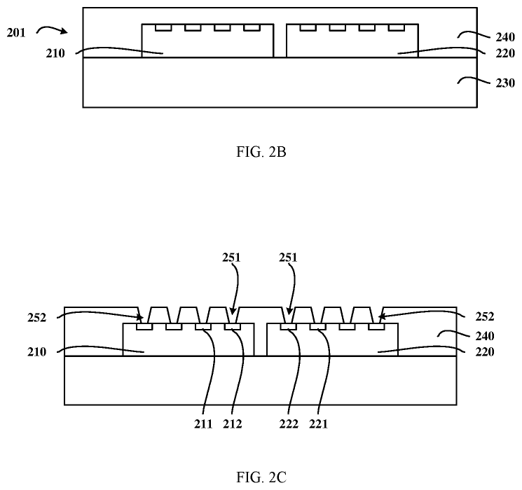

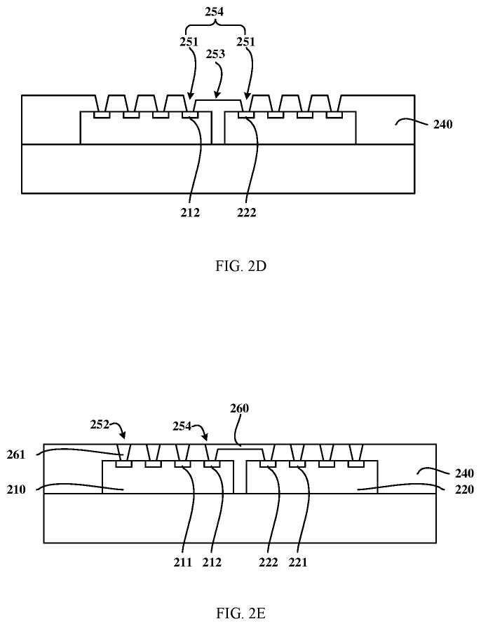

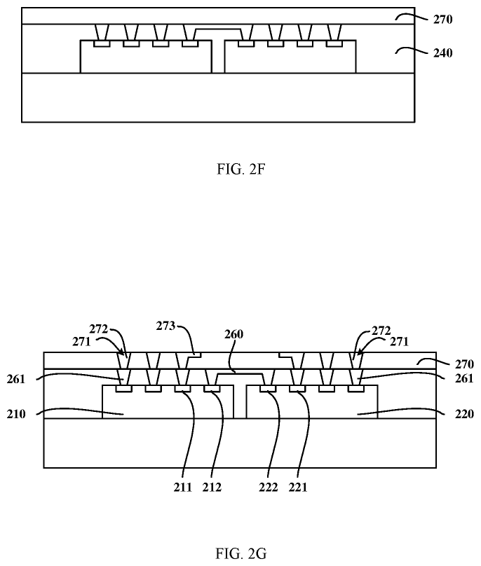

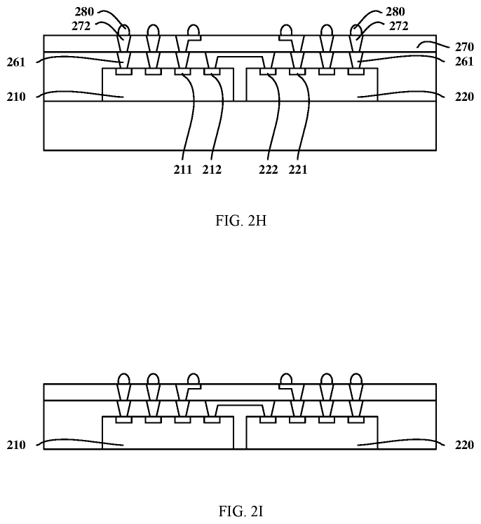

FIGS. 2A to 21 show cross-sectional views of various steps of a method for making a semiconductor device according to an embodiment of the present application.

Referring to FIG. 2A, a semiconductor assembly 201, which includes at least semiconductor dice 210 and 220, is attached on a carrier 230. In particular, the semiconductor die 210 is electrically coupled to at least one interconnection structure 212 and the semiconductor die 220 is electrically coupled to at least one interconnection structure 222. The interconnection structures 212 and 222 can be, for example, electrically coupled to the internal circuitries of the semiconductor dice 210 and 220, respectively. The at least one interconnection structure 212 can be electrically coupled to at least one interconnection structure 222 of the semiconductor die 220 in the subsequent steps. In some embodiments, the semiconductor dice 210 and 220 may also be formed with a plurality of connection structures 211 and 221 for electrically coupling the respective semiconductor dice with other electronic components. In other words, it may not be desired to connect the connection structures 211 with the connection structures 221. In some embodiments, the interconnection structures 212, 222 and the connection structures 211, 222 may be contact pads formed on the corresponding semiconductor dice 210 and 220. It can be appreciated that, the interconnection structures 212, 222 and the connection structures 211, 222 may be other structures electrically connected to the corresponding semiconductor dice 210 and 220. It can be appreciated that more semiconductor dice may be included in the semiconductor assembly 201 in some other embodiments.

The carrier 230 or other similar temporary substrate where the semiconductor dice 210 and 220 are placed may contain a sacrificial base material such as silicon, polymer, beryllium oxide, glass, or other suitable low-cost, rigid material for structural support. In some embodiments, an interface layer or double-sided tape (not shown) may be formed over the carrier 230 as a temporary adhesive bonding film, etch-stop layer, or thermal release layer. The semiconductor dice 210 and 220 are mounted to the carrier 230 using such as a pick and place operation with a back surface of the semiconductor dice oriented toward the carrier 230. In some embodiments, the carrier 230 may be mounted with multiple semiconductor dice as desired. The density of semiconductor dice on the carrier 230 may be adjusted as needed, depending on for example the scale and complexity of the system-in-package to be formed.

Still referring to FIG. 2A, as illustrated above, the semiconductor dice 210 and 220 may be coupled to each other through the interconnection structures 212 and 222. In some embodiments, at least one of the semiconductor dice 210 and 220 may be formed with a redistribution layer (not shown) for electrical connection between the semiconductor dice 210 and 220 and/or other electronic components. In the case that each semiconductor die is formed with a redistribution layer, the redistribution layer of each semiconductor die may include an interconnection structure to be directly coupled to each other. In some other embodiments, both of the two semiconductor dice may be connected to a redistribution layer, and the one redistribution layer may further include interconnection structures to be directly coupled to each other. In some embodiments, the redistribution layer may include one or more dielectric layers and one or more conductive layers between and through the dielectric layers. The redistribution layer may be electrically coupled to the semiconductor die or dice.

Referring to FIG. 2B, an encapsulant layer 240 is deposited over the carrier 230 and the semiconductor assembly 201 to encapsulate the semiconductor assembly 201. In some embodiments, the encapsulant layer 240 fully encapsulates the semiconductor dice 210 and 220 as well as the interconnection structures 212 and 222. It can be understood that the encapsulant layer 240 may also partially encapsulate the semiconductor dice 210 and 220 in some embodiments. Specifically, the encapsulant layer 240 may include a polymer composite material, such as epoxy resin with filler, epoxy acrylate with filler, or polymer with proper filler. In addition, the encapsulant layer 240 includes an additive which is activatable by laser. In some embodiments, the encapsulant layer 240 can be a laser direct structuring material layer. The laser direct structuring material layer refers to a material layer for implementing a process of selective metallization of defined regions after impingement of laser irradiation “activation” on a substrate containing an additive, which releases a metal “seed” capable of promoting the metal deposition to form a conductive pathway. In a laser direct structuring process, a laser beam travels over the molded article to activate the surface at locations where a conductive metal path is desired, thus, “structuring” the article. For example, the encapsulant layer 240 may be infused or implanted with additive activatable by laser. The additive may be a laser-activated catalyst or particles that become nuclei for a subsequent metallization when exposed to IR (infrared) laser radiation. The additive may be dispersed in the encapsulant layer 240. The additive may be spinel-based metal oxides, such as copper chromium oxide; metal salts, such as copper hydroxide phosphate; organic metal complexes, and the like. In some embodiments, the activated additive may serve as a seed layer upon laser patterning. Such seed layer may enable a subsequent plating process to be directly applied along the pattern formed with the laser patterning. Preferably, the encapsulant layer 240 is non-conductive and environmentally protects the semiconductor dice 210 and 220 from external elements and contaminants. In some embodiments, the encapsulant layer 240 may also protect the semiconductor dice 210 and 220 from degradation due to exposure to light. The encapsulant layer 240 may be deposited using paste printing, compressive molding, transfer molding, liquid encapsulant molding, vacuum lamination, spin coating, or other suitable applicator.

Referring to FIG. 2C, openings 251 are formed in the encapsulant layer 240 by laser ablation. In particular, the openings 251 are formed on the interconnection structures 212 and 222 to expose the interconnection structures 212 and 222. The openings 251 allows for further formation of an interconnection channel connecting the interconnection structures 212 and 222 as illustrated below. In some embodiments, openings 252 are also formed on the connection structures 211 and 221. The openings 252 may expose the connection structures 211 and 221 of the semiconductor dice 210 and 220, such that a conductive material may be filled in the openings 252 and connected with the exposed top surfaces of the connection structures 211 and 221. It can be understood that the power and wavelength of the laser ablation for forming the openings 251 and 252 can be controlled, such that openings 251 and 252 are formed while preserving interconnection structures 212, 222 and connection structures 211, 221. It can be understood that, respective inner surfaces of the openings 251 and 252 may be activated as the seed layer, such that subsequent plating can be directly applied on the seed layer. It can be understood that, in the embodiments where the openings 252 are also formed, the openings 252 may also be formed by laser ablation, and respective inner surface of the openings 252 may also be activated as the seed layer.

Referring to FIG. 2D, a connection bridge 253 extending between the two openings 251 on the interconnection structures 212 and 222 is formed with laser ablation. In particular, the additive activatable by laser on the surface of the connection bridge 253 is activated, and the activated additive serves as a seed layer such that subsequent plating can be directly applied along the pattern formed by the laser ablation. As shown in FIG. 2D, via laser patterning, an interconnection channel 254 including the openings 251 and the connection bridge 253 is formed, and the additive of the encapsulant layer 240 in the interconnection channel 254 is activated as the seed layer. Specifically, the interconnection channel 254 exposes and interconnects the interconnection structures 212 and 222. Preferably, the laser ablation process may adopt laser beams in the infrared range. In some embodiments, the encapsulant layer 240 under the connection bridge 253 may be depressed, for example, by several microns to several hundreds of microns, to allow that more conductive material can be formed in the connection bridge 253 through plating. The thicker the conductive material in the connection bridge 253, the better conductivity between the interconnection structures 212 and 222 is.

Referring to FIG. 2E, in the interconnection channel 254 formed in the encapsulant layer 240, a conductive layer 260 electrically coupled to the interconnection structures 212 and 222 is formed. The conductive layer 260 may be formed using a deposition process such as sputtering, electrolytic plating or electroless plating. Preferably, the conductive layer 260 is formed by electrolytic plating. In some embodiments, an electroless plating is conducted before an electrolytic plating. The conductive layer 260 can be one or more layers of Al, Cu, Sn, Ni, Au, Ag, or other suitable electrically conductive material. It can be understood that, in the embodiments where openings 252 are also formed, conductive vias 261 may also be formed within the openings 252 that are electrically coupled to the connection structures 211 and 221 of the semiconductor dice 210 and 220. That is to say, conductive vias 261 may be formed by filling with conductive materials. However, since no connection bridge is formed for the openings 252, the conductive vias 261 in the openings 252 are only electrically coupled to the respective connection structures 211 and 221 thereunder, and are generally not electrically coupled with each other.

Referring to FIG. 2F, an outer layer 270 is formed on the encapsulant layer 240. In some embodiments, the outer layer 270 may be an outer encapsulant layer 270. The outer encapsulant layer 270 may be formed with molding. In some embodiments, the outer encapsulant layer 270 may include an additive activatable by laser. The material and formation of the outer encapsulant layer 270 may refer to the encapsulant layer 240. The additive of the outer encapsulant layer 270 may or may not be the same as the additive of the encapsulant layer 240. As illustrated in other embodiments, the outer layer 270 may also be a redistribution layer with interleaving dielectric layers and conductive layers. With the activatable additive, laterally extending structures similar as the connection bridge can be formed in the outer encapsulant layer 270, facilitating the routing and wiring in the outer layer 270.

Referring to FIG. 2G, upon laser ablation, the outer encapsulant layer 270 including an additive activatable by laser may be formed with openings 271. The openings 271 may expose the conductive vias 261 electrically coupled to the connection structures 211 and 221 of the semiconductor dice 210 and 220, respectively. As can be seen, the conductive layer 260 connecting interconnection structures 212 and 222 remain not exposed from the outer encapsulant layer 270 and thus isolated from other potential conductive structures. Similar as illustrated above, conductive vias 272 are formed within the openings 271. Through the conductive vias 261, the conductive vias 272 are electrically coupled to the connection structures 211 and 221 of the semiconductor dice 210 and 220, respectively. The aforementioned conductive vias 261, 271 may have straight or tapered sidewalls. It can be understood that, in the case that the outer encapsulant layer 270 does not include an additive activatable by laser, conductive vias 272 may also be formed with laser ablation and metal deposition process such as printing, PVD, CVD, sputtering, electrolytic plating, and electroless plating. It can be understood that, the conductive vias 272 may include laterally extending conductive structures 273 which provide larger area for electrical coupling, as aforementioned.

Referring to FIG. 2H, solder balls 280 are mounted on the outer encapsulant layer 270 and electrically coupled to the conductive vias 272, such that the solder balls 280 are electrically coupled to the connection structure 211 of the semiconductor die 210 and the connection structure 221 of the semiconductor die 220 via the corresponding conductive vias 272 and the corresponding conductive vias 261. In some embodiments, the solder balls 280 may be formed by e.g. depositing electrically conductive bump material using evaporation, electrolytic plating, electroless plating, ball drop, or screen printing process. The bump material can be Al, Sn, Ni, Au, Ag, Pb, Bi, Cu, solder, and combinations thereof, with an optional flux solution. The bump material is bonded to the outer encapsulant layer 270 using a suitable attachment or bonding process. In some embodiments, the bump material is reflowed by heating the material above its melting point to form the solder balls 280.

Referring to FIG. 21, the carrier is detached from the formed semiconductor device to expose the back surface of the semiconductor dice 210 and 220. In some embodiments, the carrier is removed by chemical etching, mechanical peeling, CMP, mechanical grinding, thermal bake, UV light, laser scanning, or wet stripping. In some embodiments where multiple sets of semiconductor assemblies are encapsulated through the process shown in FIGS. 2A to 2H, the semiconductor devices can be singulated from each other, for example, using laser singulation or mechanical singulation such as sawing.

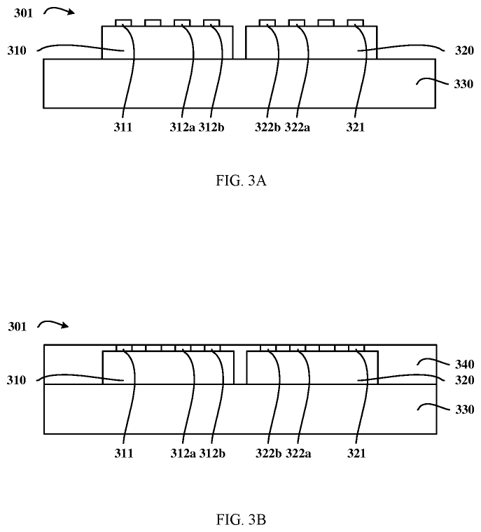

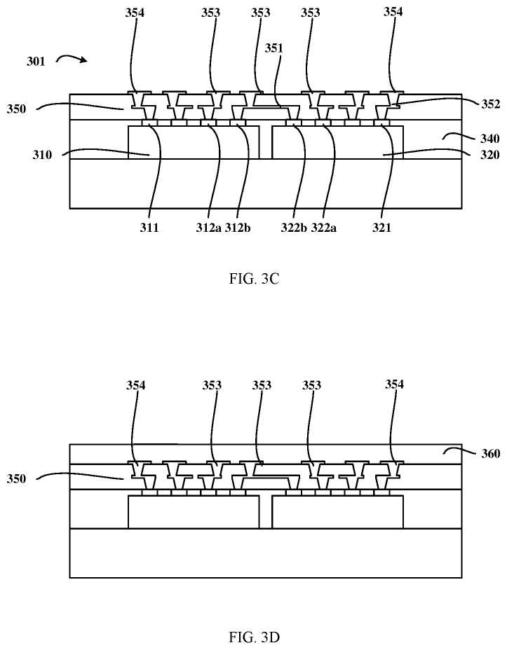

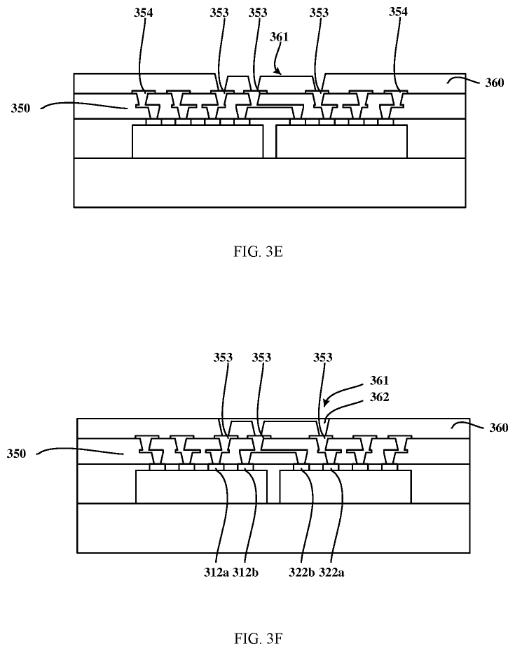

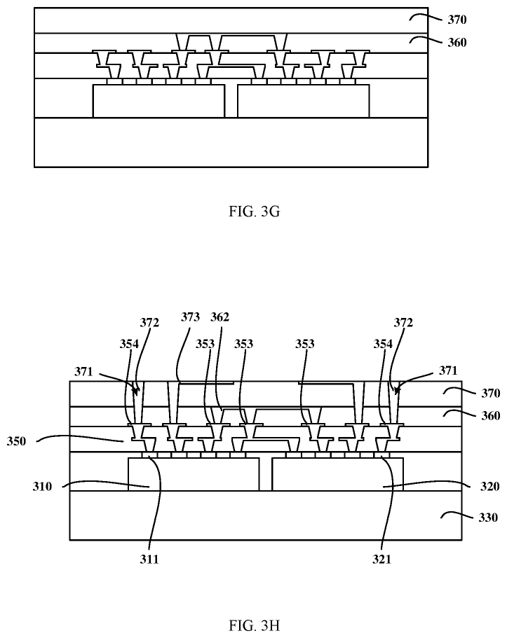

FIGS. 3A to 31 are cross-sectional views illustrating various steps of a method for making a semiconductor device according to another embodiment of the present application. Similar as in the method shown in FIGS. 2A to 21, the semiconductor device formed using the method shown in FIGS. 3A to 31 includes a connection bridge in an encapsulant layer, and the connection bridge is not exposed from the semiconductor device. In addition, different from the semiconductor assembly 201 including separated semiconductor dice 210, 220 shown in FIG. 2A, on the semiconductor dice is formed with a common redistribution layer.

Referring to FIG. 3A, a semiconductor assembly 301 including at least semiconductor dice 310 and 320 is attached on a carrier 330. In particular, the semiconductor assembly 301 includes interconnection structures 312a, 312b to be electrically coupled to interconnection structures 322a, 322b. The interconnection structures 312a, 312b are associated with and electrically coupled to the semiconductor die 310, while the interconnection structures 322a, 322b are associated with and electrically coupled to the semiconductor die 320. In other embodiments, the semiconductor die 310 or 320 may be coupled to other number of interconnection structures. In some embodiments, the semiconductor dice 310 and 320 may also be coupled to a plurality of connection structures 311 and 321 for electrically coupling the respective semiconductor dice with other electronic components. In some embodiments, the interconnection structures 312a, 312b and 322a, 322b, and the connection structures 311 and 321 may be contact pads formed on the respective semiconductor dice. It can be appreciated that, the interconnection structures 312a, 312b and 322a, 322b, and the connection structures 311 and 321 may be other structures electrically connected to the respective semiconductor dice 310 and 320. The semiconductor dice 310 and 320 are mounted to the carrier 330 or other similar temporary substrate. The configuration of the carrier 330 may refer to the carrier 230 as shown in FIGS. 2A to 21 and will not be elaborated herein.

As shown in FIGS. 3B and 3C, in some embodiments, the semiconductor dice 310 and 320 may be coupled to a redistribution layer 350. The one redistribution layer 350 may or may not electrically couple the semiconductor dice as needed. It can be understood that, in other embodiments, at least one of the semiconductor dice 310 and 320 may include a redistribution layer for electrical connection with each other and/or other electronic components.

Referring to FIG. 3B, an encapsulant layer 340 is deposited over the carrier 330 to encapsulate the semiconductor assembly 301. Preferably, the encapsulant layer 340 may encapsulate the semiconductor dice 310 and 320 while exposing the interconnection structures 312a, 312b and 322a, 322b, and the connection structures 311 and 321. The encapsulant layer 340 may include polymer composite material, such as epoxy resin with filler, epoxy acrylate with filler, or polymer with proper filler. Preferably, the encapsulant layer 340 is non-conductive and environmentally protects the semiconductor dice 310 and 320 from external elements and contaminants. In some embodiments, the encapsulant layer 340 may also protect semiconductor dice 310 and 320 from degradation due to exposure to light. The encapsulant layer 340 may be formed using paste printing, compressive molding, transfer molding, liquid encapsulant molding, vacuum lamination, spin coating, or other suitable applicator.

Referring to FIG. 3C, the redistribution layer 350 is formed on the encapsulant layer 340. The redistribution layer 350 may include one or more dielectric layers and one or more conductive layers between and through the dielectric layers. In general, the redistribution layer 350 redistributes the locations of the electrical connections of the semiconductor dice 310 and 320 to desired locations, and the redistribution layer 350 may also interconnect some of the electrical connections of the semiconductor dice 310 and 320. In particular, the redistribution layer 350 may include an inner connection structure 351 that is electrically coupled to the interconnection structures 312b and 322b, and the redistribution layer 350 may also include inner connection structures 352 that are electrically coupled to the connection structures 311, 321 of the semiconductor assembly 301. Specifically, the inner connection structure 351 may be configured to electrically couple interconnection structures 312b and 322b of the semiconductor assembly 301 to an interconnection structure 353 on the redistribution layer 350, and the inner connection structure 352 may be configured to electrically couple the interconnection structures 312a and 322a to the interconnection structures 353 on the redistribution layer 350. The inner connection structure 352 may also be configured to electrically couple the connection structures 311, 321 to a connection structures 354. As a result, the interconnection structures 312a, 312b, 322a, 322b are partially connected within the redistribution layer 350 and are redistributed to the interconnection structures 353 on the redistribution layer 350. Also, the redistribution layer 350 redistributes the connection structures 311, 321 to the connection structures 354 on the redistribution layer 350. It can be understood that, the redistribution layer 350 may or may not include the inner connection structure 351 that connects semiconductor dice 310 and 320 of the semiconductor assembly 301. Aspects of the present application are not limited thereto.

Referring to FIG. 3D, similar as FIG. 2B, an encapsulant layer 360 is deposited over the redistribution layer 350 and encapsulates the connection structures 354 and the interconnection structures 353 of the redistribution layer 350. Specifically, the encapsulant layer 360 includes an additive that is activatable by laser. The material of the encapsulant layer 360 and the method for applying such encapsulant layer 360 may refer to the descriptions of the encapsulant layer 240 shown in FIG. 2B and will not be elaborated herein.

Referring to FIG. 3E, similar as FIGS. 2C and 2D, an interconnection channel 361 including openings and connection bridges is formed in the encapsulant layer 360 by laser patterning. In particular, the interconnection channel 361 is formed on the interconnection structures 353 of the redistribution layer 350, and the interconnection channel 361 exposes and interconnects the interconnection structures 353. In some embodiments, the openings on the connection structures 354 of the redistribution layer 350 are not formed at this stage. The formation of the interconnection channel 361 may refer to the descriptions of the interconnection channel 254 shown in FIGS. 2C and 2D and will not be elaborated herein. It can be understood that, in some embodiments, the openings may also be formed on the connection structures 354 of the redistribution layer 350.

Referring to FIG. 3F, similar as FIG. 2E, in the interconnection channel 361 of the encapsulant layer 360, a conductive layer 362 is formed using a deposition process such as sputtering, electrolytic plating or electroless plating. Preferably, since the encapsulant layer 360 includes an additive activatable by laser, which facilitates direct subsequent plating, the conductive layer 362 is preferably formed by plating. As can be seen in FIG. 3F, the conductive layer 362 electrically couples the interconnection structures 353 of the redistribution layer 350. Therefore, the interconnection structures 312a, 312b, 322a, 322b are electrically coupled to each other after the aforementioned steps. The formation of the conductive layer 362 may refer to the descriptions of the conductive layer 260 shown in FIG. 2E and will not be elaborated herein.

Referring to FIG. 3G, similar as FIG. 2F, an outer layer 370 is formed on the encapsulant layer 360. In some embodiments, the outer layer 370 may be an outer encapsulant layer 370. The outer encapsulant layer 370 may be formed with molding. In some embodiments, the outer encapsulant 370 may include an additive activatable by laser. As illustrated in other embodiments, the outer layer 370 may also be a redistribution layer with interleaving dielectric layers and conductive layers. The additive of the outer encapsulant layer 370 may be the same or different from the additive of the encapsulant layer 360. The material and formation of the outer encapsulant layer 370 may refer to the outer encapsulant layer 270 as shown in FIG. 2F, and will not be elaborated herein.

Referring to FIG. 3H, similar as FIG. 2G, by laser ablation, the outer encapsulant layer 370 and the encapsulant layer 360 may be formed with openings 371 which expose the connection structures 354 of the redistribution layer 350 electrically coupled to the connection structures 311 and 321 of the semiconductor dice 310 and 320, respectively. As can be seen, the conductive layer 362 connecting interconnection structures 353 of the redistribution layer 350 remain not exposed from the outer encapsulant layer 370. Similar as illustrated above, conductive vias 372 are formed within the openings 371, and the conductive vias 372 are electrically coupled to the connection structures 354 of the redistribution layer 350, therefore electrically coupled to the connection structures 311 and 321 of the semiconductor dice 310 and 320, respectively. It can be understood that, in some embodiments, the formation of the openings may be completed in a two-step manner in the encapsulant layer 360 and the outer encapsulant layer 370. Aspects of the present application are not limited thereto. It can also be understood that, the conductive vias 372 may include laterally extending conductive structures 373 which provide larger area for electrical coupling.

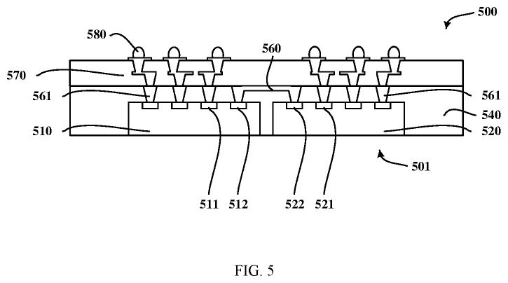

Referring to FIG. 31, similar as FIG. 2H and FIG. 21, solder balls 380 are mounted on the outer encapsulant layer 370 and electrically coupled to the conductive vias 372, such that the solder balls 380 are electrically coupled to the connection structure 311 of the semiconductor die 310 and the connection structure 321 of the semiconductor die 320 via the corresponding conductive vias 371 and the redistribution layer 350. The material and formation of the solder balls may refer to the solder balls 280 as shown in FIGS. 2H and 21, and will not be elaborated herein. Also, as can be seen in the formed semiconductor device, the conductive layer 362 electrically coupling the interconnection structures 312a, 312b, 322a, 322b is not exposed. Still referring to FIG. 31, the carrier 330 shown in FIG. 3H is detached from the formed semiconductor device.

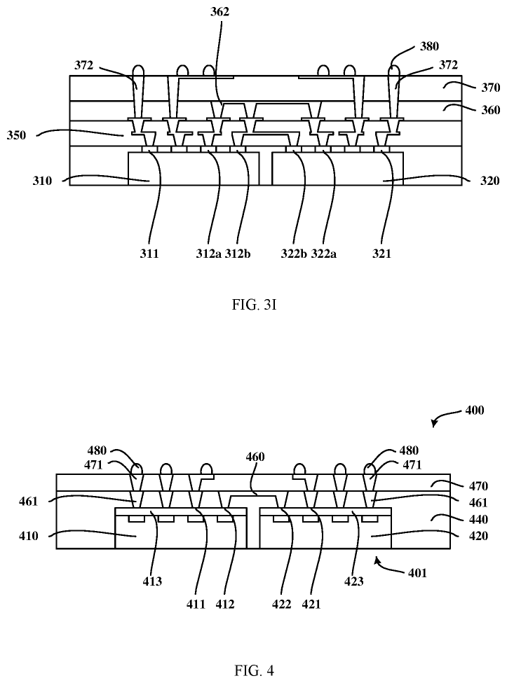

FIGS. 4 and 5 show cross-sectional views of two semiconductor devices 400 and 500 formed with method of the present application according to other embodiments of the present application.

Referring to FIG. 4, the semiconductor device 400 includes a semiconductor assembly 401 including semiconductor dice 410 and 420. The semiconductor assembly 401 also includes interconnection structures 412 and 422 formed on redistribution layers 413 and 423, respectively. The interconnection structures 412 and 422 are electrically coupled to the semiconductor die 410 and the semiconductor die 420 via the redistribution layers 413 and 423, respectively. An encapsulant layer 440 encapsulates the semiconductor assembly 401, including an additive activatable by laser. The material and formation of the encapsulant layer 440 may refer to the encapsulant layer 240 shown in FIGS. 2A to 21. A conductive layer 460 is formed in the encapsulant layer 440. The conductive layer 460 interconnects the interconnection structures 412 and 422 of the semiconductor assembly 401. The conductive layer 460 is formed by activating the additive in the encapsulant layer 440 as a seed layer using laser patterning and subsequent plating on the seed layer. The material and formation of the conductive layer 460 may refer to the conductive layer 260 shown in FIGS. 2A to 21. Also, an outer layer 470 is formed on the encapsulant layer 440 to cover the conductive layer 460. In some embodiments, the semiconductor assembly 401 also includes connection structures 411 and 421 on the redistribution layers 413 and 423, respectively. In the encapsulant layer 440, conductive vias 461 may be formed via laser ablation and subsequent conductive material filling, and conductive vias 461 may be electrically coupled to the corresponding connection structure 411 or 421. In some embodiments, the outer layer 470 is an outer encapsulant layer 470 including an additive activatable by laser. The outer encapsulant layer 470 is also formed with conductive vias 471 electrically coupled to the conductive vias 461, thereby electrically coupled to the connection structures 411 and 421. In some embodiments, the semiconductor device 400 also includes solder balls 480.

Referring to FIG. 5, the semiconductor device 500 includes a semiconductor assembly 501 including semiconductor dice 510 and 520. The semiconductor assembly 501 also includes interconnection structures 512 and 522 on the semiconductor dice 510 and 520, respectively. An encapsulant layer 540 encapsulates the semiconductor assembly 501, including an additive activatable by laser. The material and formation of the encapsulant layer 540 may refer to the encapsulant layer 240 shown in FIGS. 2A to 21. A conductive layer 560 is formed in the encapsulant layer 540. The conductive layer 560 interconnects the interconnection structures 512 and 522 of the semiconductor assembly 501. The conductive layer 560 is formed by activating the additive in the encapsulant layer 540 as a seed layer using laser patterning and subsequent plating on the seed layer. The material and formation of the conductive layer 560 may refer to the conductive layer 260 shown in FIGS. 2A to 21. Also, an outer layer 570 is formed on the encapsulant layer 540 to cover the conductive layer 560. In some embodiments, the semiconductor assembly 501 also includes connection structures 511 and 521. In the encapsulant layer 540, conductive vias 561 are formed to be electrically coupled to the corresponding connection structure 511 or 521. In some embodiments, the outer layer 570 is a redistribution layer 570 electrically coupled to the conductive vias 561, thereby electrically coupled to the connection structures 511 and 521. The redistribution layer 570 enables electrical connection of the connection structures 511 and 521 of the semiconductor assembly 501 with exterior components at desired locations. In some embodiments, the semiconductor device 500 also includes solder balls 580.

As can be seen in the above embodiments, the subject underneath the encapsulant layer where a conductive layer is formed may be a) semiconductor dice; b) semiconductor dice with respective redistribution layer; c) semiconductor dice with one common redistribution layer. The subject above the encapsulant layer where a conductive layer is formed may be a) redistribution layer; b) outer encapsulant layer.

The discussion herein included numerous illustrative figures that showed various portions of a semiconductive device and a method for manufacturing such semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor device, comprising:
providing a semiconductor assembly comprising a first semiconductor die and a second semiconductor die, wherein a first interconnection structure is electrically coupled to the first semiconductor die and a second interconnection structure is electrically coupled to the second semiconductor die;
depositing an encapsulant layer over the semiconductor assembly to encapsulate the first interconnection structure and the second interconnection structure, wherein the encapsulant layer comprises an additive activatable by laser;
forming an interconnection channel in the encapsulant layer and activating the additive of the encapsulant layer in the interconnection channel as a seed layer by laser patterning, wherein the interconnection channel exposes and interconnects the first and the second interconnection structures;
forming a conductive layer in the interconnection channel of the encapsulant layer; and
forming an outer layer on the encapsulant layer to cover the conductive layer.

2. The method of claim 1, wherein the semiconductor assembly further comprises a plurality of connection structures electrically coupled to the first semiconductor die and the second semiconductor die, the outer layer is a redistribution layer; and the method further comprising:
forming openings in the encapsulant layer to expose the plurality of connection structures; and
forming conductive vias in the openings electrically coupled to the plurality of connection structures.

3. The method of claim 1, wherein the semiconductor assembly further comprises a plurality of connection structures electrically coupled to the first semiconductor die and the second semiconductor die, the outer layer is an outer encapsulant layer comprising an additive activatable by laser; and the method further comprising:
forming openings in the encapsulant layer and the outer encapsulant layer to expose the plurality of connection structures; and
forming conductive vias in the openings electrically coupled to the plurality of connection structures.

4. The method of claim 2, wherein the openings of the conductive vias are formed by laser ablation.

5. The method of claim 3, wherein the openings of the conductive vias are formed by laser ablation.

6. The method of claim 1, wherein the first interconnection structure and the second interconnection structure are contact pads formed on the first semiconductor die and the second semiconductor die, respectively.

7. The method of claim 1, wherein the first interconnection structure and the second interconnection structure are conductive structures on redistribution layers formed on the first semiconductor die and the second semiconductor die, respectively.

8. The method of claim 1, wherein the first interconnection structure and the second interconnection structure are conductive structures on a redistribution layer formed on the first semiconductor die and the second semiconductor die.

9. A semiconductor device, comprising:
a semiconductor assembly comprising a first semiconductor die and a second semiconductor die, wherein a first interconnection structure and a second interconnection structure are electrically coupled to the first semiconductor die and the second semiconductor die, respectively;
an encapsulant layer over the semiconductor assembly, wherein the encapsulant layer encapsulates the first interconnection structure and the second interconnection structure, wherein the encapsulant layer comprises an additive activatable by laser;
a conductive layer formed in the encapsulant layer, wherein the conductive layer interconnects the first and the second interconnection structures of the semiconductor assembly; wherein the conductive layer is formed by activating the additive of the encapsulant layer as a seed layer using laser patterning and subsequent plating on the seed layer; and
an outer layer formed on the encapsulant layer to cover the conductive layer.

10. The semiconductor device of claim 9, wherein the semiconductor assembly further comprises a plurality of connection structures electrically coupled to the first semiconductor die and the second semiconductor die, the outer layer is a redistribution layer; and the semiconductor device further comprising conductive vias in the encapsulant layer electrically coupled to the plurality of connection structures.

11. The semiconductor device of claim 9, wherein the semiconductor assembly further comprises a plurality of connection structures electrically coupled to the first semiconductor die and the second semiconductor die; wherein the outer layer is an outer encapsulant layer comprising an additive activatable by laser; and the semiconductor device further comprising conductive vias in the encapsulant layer and the outer encapsulant layer electrically coupled to the plurality of connection structures.

12. The semiconductor device of claim 10, wherein the conductive vias are formed by laser ablation and subsequent conductive material filling.

13. The semiconductor device of claim 11, wherein the conductive vias are formed by laser ablation and subsequent conductive material filling.

14. The semiconductor device of claim 9, wherein the first interconnection structure and the second interconnection structure are contact pads formed on the first semiconductor die and the second semiconductor die, respectively.

15. The semiconductor device of claim 9, wherein the first interconnection structure and the second interconnection structure are conductive structures on redistribution layers formed on the first semiconductor die and the second semiconductor die, respectively.

16. The semiconductor device of claim 9, wherein the first interconnection structure and the second interconnection structure are conductive structures on a redistribution layer formed on the first semiconductor die and the second semiconductor die.
